(19) United States
(12) Patent Application Publication
(10) Pub. No.: US 2005/0176241 A1
(43) Pub. Date: Aug. 11, 2005

(54) Method of forming metal wiring of semiconductor devices

(75) Inventor: Sang Wook Ryu, Chungcheongbuk-do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: Magnachip Semiconductor., Ltd., Chungcheongbuk-do (KR)

(21) Appl. No.: 11/052,483

(22) Filed: Feb. 4, 2005

(30) Foreign Application Priority Data
Feb. 6, 2004 (KR) 2004-8029

(51) Int. Cl. H01L 21/4763

(52) U.S. Cl. 438/633; 438/634

(57) ABSTRACT

Disclosed herein is a method of forming metal wirings of semiconductor devices a lower metal wiring is formed in a dual damascene pattern formed in an interlayer insulating film and is etched as much as a given thickness of the interlayer insulating film, thereby exposing the top of the lower metal wiring. A via plug is then formed on the exposed top of the lower metal wiring. Accordingly, even if alignment error is generated, increases of resistance, which is caused by contact of the via plug and the lower metal wiring through the sidewall of the projected lower metal wiring, can be prevented. Furthermore, reliability of a process and electrical properties of the devices can be improved.

### BACKGROUND

1. Field of the Invention

The present invention relates to a method of forming metal wirings of semiconductor devices, and more specifically, to a method of forming metal wirings of semiconductor devices in which increase of contact resistance due to alignment error can be prevented.

2. Discussion of Related Art

The highest object in semiconductor manufacture techniques lies in a high integration level and high performance of semiconductor devices. The most important factor in realizing a high integration level and high performance is a copper wiring process. However, copper (Cu) has a problem in that it is rarely etched by means of a common etch material. For this reason, the copper wiring is usually formed in such a manner that a dual damascene pattern composed of a via hole and a trench is first formed in an insulating film by means of a dual damascene process, and the dual damascene pattern is then buried with copper.

In applying the dual damascene process, to exactly align the via hole and the trench is very important. No matter how exactly the via hole and the trench are aligned, alignment error inevitably occurs.

FIG. 1 is a cross-sectional photograph showing alignment error between a lower metal wiring and a via plug.

Referring to FIG. 1, if alignment error occurs between a lower metal wiring 101 and a via plug 102 formed on the lower metal wiring 101, a parasitic fence 103 is generated. If the parasitic fence 103 is generated, a contact area between the via plug 102 and the lower metal wiring 101 decreases.

If the diameter of a via hole in process technologies of below 0.09 um is about 0.16 um, a contact radius is reduced to 0.13 um although alignment error occurs only 30 nm. Thus, there occur problems that reliability of a process and electrical properties of a device are lowered because contact resistance increases.

### SUMMARY OF THE INVENTION

Accordingly, the present invention has been made in view of the above problems, and it is an object of the present invention to provide a method of forming metal wirings of semiconductor devices in which a lower metal wiring is formed in a dual damascene pattern formed in an interlayer insulating film and is etched as much as a given thickness of the interlayer insulating film, thus exposing the top of the lower metal wiring, and a via plug is then formed on the exposed top of the lower metal wiring, whereby increases of resistance, which is caused by contact of the via plug and the lower metal wiring through the sidewall of the projected lower metal wiring, is prevented even when alignment error is generated, and reliability of a process and electrical properties of the devices can be improved.

To achieve the above object, according to an embodiment of the present invention, there is provided a method of forming metal wirings of semiconductor devices, comprising the steps of forming a first interlayer insulating film on a semiconductor substrate, and forming a dual damascene pattern in the first interlayer insulating film, forming a first metal wiring within the dual damascene pattern, removing the top of the first interlayer insulating film by a given thickness, thus exposing the top of the first metal wiring, performing a rounding process to make top corners of the projected first metal wiring round, forming a second interlayer insulating film on the entire surface including the first metal wiring, and forming a dual damascene pattern in the second interlayer insulating film, and forming a second metal wiring within the dual damascene pattern of the second interlayer insulating film.

In the above, during an etch process for etching the first interlayer insulating film, BOE can be used as an etchant. Preferably, an etch thickness of the first interlayer insulating film is 50 Å to 2000 Å.

The rounding process can be performed in a sputtering dry etch process. During the sputtering dry etch process, a gas containing inert atom or halogen atom or a gas containing inert molecule such as O₂ or N₂ can be used, or a combination of those gases can be used.

That is, CxHyFz (x, y, z are 0 or a natural number), SF₆, Cl₂, F₂, HBr or HI can be used as the etch gas.

The method may further comprises the step of, after the rounding process is performed, performing a cleaning process by using a solution containing fluorine, such as HF or BOE, or a solution which contains amine as an essential component, such as NH₂OH or NH₄OH.

### BRIEF DESCRIPTION OF THE DRAWINGS

FIG. 1 is a cross-sectional photograph showing alignment error between a lower metal wiring and a via plug; and

FIGS. 2a to 2d are sectional views for explaining a method of forming metal wirings in semiconductor devices according to an embodiment of the present invention.

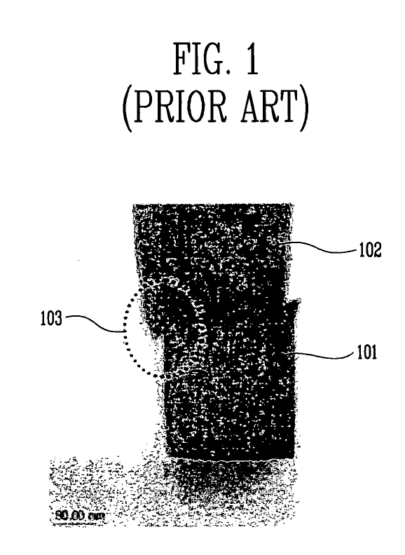

### DETAILED DESCRIPTION OF PREFERRED EMBODIMENTS

Now, the preferred embodiments according to the present invention will be described with reference to the accompanying drawings. Since preferred embodiments are provided for the purpose that the ordinary skilled in the art are able to understand the present invention, they may be modified in various manners and the scope of the present invention is not limited by the preferred embodiments described later. Further, in the drawing, the thickness and size of each layer are exaggerated for explanation's convenience and clarity. Like reference numerals are used to identify the same or similar parts. Meanwhile, in case where it is described that one film is “on” the other film or a semiconductor substrate, the one film may directly contact the other film or the semiconductor substrate. Or, a third film may be intervened between the one film and the other film or the semiconductor substrate.

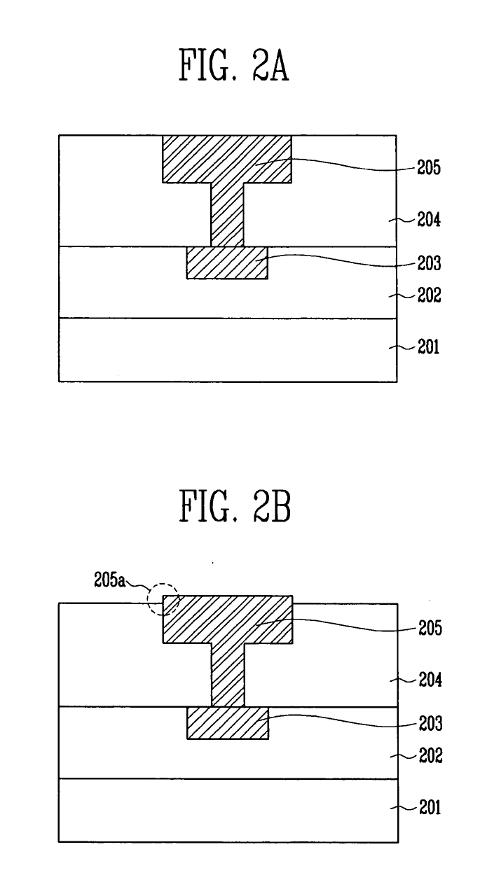

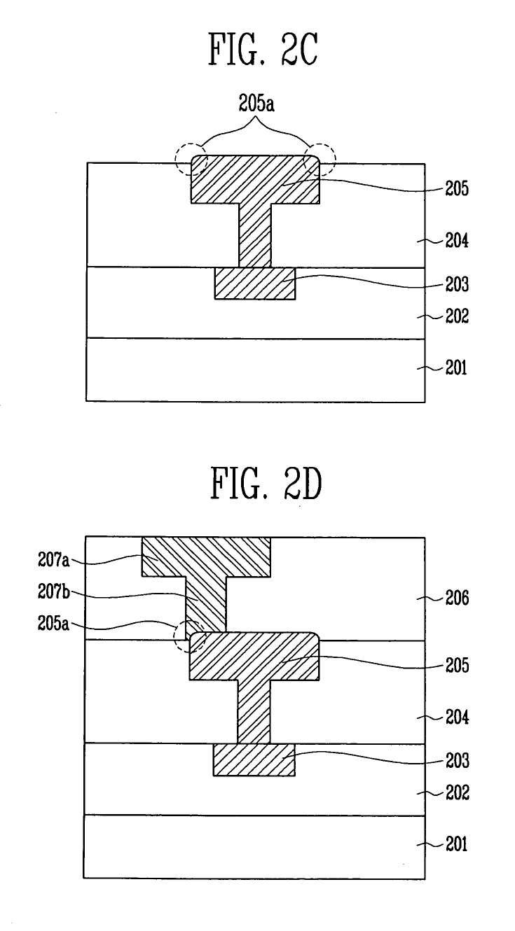

FIGS. 2a to 2d are sectional views for explaining a method of forming metal wirings in semiconductor devices according to an embodiment of the present invention.

Referring to FIG. 2a, a semiconductor substrate 201 in which various elements for forming a semiconductor device are formed is prepared. For example, transistors or memory cells (not shown) can be formed in the semiconductor substrate 201. After a first interlayer insulating film 202 is formed on the semiconductor substrate 201, a dual damascene pattern composed of a contact hole (not shown) and a trench is formed in the first interlayer insulating film 202 by means of a dual damascene process. The dual damascene pattern is buried with a conductive material to form a first metal wiring 203. In this time, the first metal wiring 203 can be formed using copper. Meanwhile, in order for the metal component of the first metal wiring 203 to diffuse into the first interlayer insulating film 202, a barrier metal layer (not shown) may be formed between the first metal wiring 203 and the first interlayer insulating film 202.

A capping layer (not shown) may be formed on the first interlayer insulating film 202. The capping layer can be formed by using a single film such as a nitride film, an oxynitride film or such as a carbonaceous layer such as SiC, or a combination of them.

An anti-diffusion film (not shown) and a second interlayer insulating film 204 are formed on the entire surface. A dual damascene pattern composed of a via hole and a trench is then formed in the second interlayer insulating film 204 by means of a dual damascene process.

Next, a barrier metal layer (not shown) is formed on the entire surface including the dual damascene pattern. A metal seed layer (not shown) is then formed on the barrier metal layer within the dual damascene pattern. Thereafter, the dual damascene pattern is buried with a metal material to form a second metal wiring 205.

In this time, in order to prevent the insulating film in which the via hole is formed from being etched during the etch process for forming the trench, an etch stop layer is used. The etch stop layer can be formed using SiC SiN or SiON. Meanwhile, the first interlayer insulating film 202 or the second interlayer insulating film 204 can be formed by using a material in which fluorine, hydrogen or the like is combined with SiO₂ or SiO₂ or a material such as PE-TEOS, USG and FSG.

Referring to FIG. 2b, the top of the second metal wiring 204 is projected by etching the top of the second interlayer insulating film 205 by a given thickness. Thereby, top corners 205a of the second metal wiring 204 are projected in a pointed shape. In this time, during the etch process, an etchant such as BOE (Buffered Oxide Etchant) can be used. The etch thickness of the second interlayer insulating film 205 is preferred controlled to a thickness of 50 Å to 2000 Å.

Referring to FIG. 2c, the top corners 205a of the second metal wiring 205, which is sharply pointed, undergo a rounding process. The rounding process is performed at a temperature of at least 10° C., preferably at high temperature of 150° C. or more. Meanwhile, the rounding process can be performed in a sputtering dry etch mode by using a gas containing inert atom or halogen atom or a gas containing inert molecule such as O₂ or N₂, or a combination of those gases. In this time, the inert atom can be He, Ne, Ar, Kr or Xe, and the halogen atom can be F, Cl or Br. CxHyFz (x, y, z are 0 or a natural number), SF₆, Cl₂, F₂, HBr or HI can be used as the etch gas containing the inert atom or the halogen atom.

After the top corners 205a of the second metal wiring 205 are made round by the rounding process, in order to remove residue generated during the rounding process, it is preferred that a cleaning process is performed by using a solution containing fluorine, such as HF or BOE, or a solution which contains amine as an essential component, such as NH₂OH or NH₄OH.

Referring to FIG. 2d, an anti-diffusion film (not shown) and a third interlayer insulating film 206 are sequentially formed on the entire surface including the second metal wiring 205. A dual damascene pattern is then formed in the third interlayer insulating film 206, and a third metal wiring 207a and a via plug 207b are formed within the dual damascene pattern.

In this time, although alignment error is generated during the process of forming the dual damascene pattern, it is possible to prevent a fence from being formed between the via plug 207b and the second metal wiring 205 or a contact area between them from reducing because the top corners 205a of the second metal wiring 205 are formed to be round.

As described above, according to the present invention, a lower metal wiring is formed in a dual damascene pattern formed in an interlayer insulating film and is etched as much as a given thickness of the interlayer insulating film, thereby exposing the top of the lower metal wiring. A via plug is then formed on the exposed top of the lower metal wiring. Accordingly, even if alignment error is generated, increases of resistance, which is caused by contact of the via plug and the lower metal wiring through the sidewall of the projected lower metal wiring, can be prevented. Furthermore, reliability of a process and electrical properties of the devices can be improved.

1. A method of forming metal wirings of semiconductor devices, comprising the steps of:
(a) forming a first interlayer insulating film on a semiconductor substrate, and forming a dual damascene pattern in the first interlayer insulating film;
(b) forming a first metal wiring within the dual damascene pattern;
(c) removing the top of the first interlayer insulating film by a given thickness, thus exposing the top of the first metal wiring;
(d) performing a rounding process to make top corners of the projected first metal wiring round;
(e) forming a second interlayer insulating film on the entire surface including the first metal wiring, and forming a dual damascene pattern in the second interlayer insulating film; and
(f) forming a second metal wiring within the dual damascene pattern of the second interlayer insulating film.

2. The method as claimed in claim 1, wherein during an etch process for etching the first interlayer insulating film, BOE is used as an etchant.

3. The method as claimed in claim 1, wherein an etch thickness of the first interlayer insulating film is 50 Å to 2000 Å.

4. The method as claimed in claim 1, wherein the rounding process is performed in a sputtering dry etch process.

5. The method as claimed in claim 4, wherein during the sputtering dry etch process, a gas containing inert atom or halogen atom or a gas containing inert molecule such as O₂ or N₂ is used, or a combination of those gases is used.

6. The method as claimed in claim 5, wherein the etch gas is CxHyFz (x, y, z are 0 or a natural number), SF₆, Cl₂, F₂, HBr or HI.

7. The method as claimed in claim 1, further comprising the step of, after the rounding process is performed, performing a cleaning process by using a solution containing fluorine, such as HF or BOE, or a solution which contains amine as an essential component, such as NH₂OH or NH₄OH.
